(19) United States
(12) Patent Application Publication
(10) Pub. No.: US 2026/0059969 A1
(43) Pub. Date: Feb. 26, 2026

(54) DISPLAY DEVICE AND METHOD OF MANUFACTURING DISPLAY DEVICE

(71) Applicant: Magnolia White Corporation, Tokyo (JP)

(72) Inventor: Yoshimasa FUJITA, Tokyo (JP)

(73) Assignee: Magnolia White Corporation, Tokyo (JP)

(21) Appl. No.: 19/302,136

(22) Filed: Aug. 18, 2025

(30) Foreign Application Priority Data
Aug. 22, 2024 (JP) 2024-140912

(51) Int. Cl. H10K 59/80; H10K 59/12; H10K 59/122

(52) U.S. Cl. CPC H10K 59/80516; H10K 59/1201; H10K 59/122

(57) ABSTRACT

According to one embodiment, a display device includes a substrate having a display area for displaying images, an insulating layer provided above the substrate, and a display element including a first electrode provided above the insulating layer in the display area. The first electrode includes a transparent first conductive oxide layer and a transparent second conductive oxide layer covering the first conductive oxide layer. Further, a transmittance of the first conductive oxide layer is higher than that of the second conductive oxide layer.

### CROSS-REFERENCE TO RELATED APPLICATIONS

This application is based upon and claims the benefit of priority from Japanese Patent Application No. 2024-140912, filed Aug. 22, 2024, the entire contents of which are incorporated herein by reference.

### FIELD

Embodiments described herein relate generally to a display device and a manufacturing method thereof.

### BACKGROUND

Recently, display devices with organic light-emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of a display panel along the III-III line of FIG. 2.

FIG. 4 is a schematic cross-sectional view showing an example of a configuration applicable to a lower electrode.

FIG. 5 is a schematic plan view of a mother substrate according to the embodiment.

FIG. 6 is a flowchart showing an example of the manufacturing method of the display device according to the first embodiment.

FIG. 7A is a schematic cross-sectional view showing the manufacturing process of the display device.

FIG. 7B is a schematic cross-sectional view of a process following FIG. 7A.

FIG. 7C is a schematic cross-sectional view of a process following FIG. 7B.

FIG. 7D is a schematic cross-sectional view of a process following FIG. 7C.

FIG. 7E is a schematic cross-sectional view of a process following FIG. 7D.

FIG. 8A is a schematic cross-sectional view of a process following FIG. 7E.

FIG. 8B is a schematic cross-sectional view of a process following FIG. 8A.

FIG. 8C is a schematic cross-sectional view of a process following FIG. 8B.

FIG. 8D is a schematic cross-sectional view of a process following FIG. 8C.

FIG. 8E is a schematic cross-sectional view of a process following FIG. 8D.

FIG. 8F is a schematic cross-sectional view of a process following FIG. 8E.

FIG. 8G is a schematic cross-sectional view showing a process following FIG. 8F.

FIG. 8H is a schematic cross-sectional view showing a process following FIG. 8G.

FIG. 8I is a schematic cross-sectional view showing a process following FIG. 8H.

FIG. 9 is a table showing an example of film formation conditions of a conductive oxide layer.

FIG. 10 is a graph showing a transmittance of a conductive oxide layer formed to a thickness of 7 nm.

FIG. 11 is a graph showing a transmittance of a conductive oxide layer formed to a thickness of 11 nm.

FIG. 12 is a graph showing a transmittance of a conductive oxide layer formed to a thickness of 25 nm.

FIG. 13 is a schematic cross-sectional view showing a configuration example of a lower electrode of the second embodiment.

### DETAILED DESCRIPTION

In general, according to one embodiment, a display device includes a substrate having a display area for displaying images, an insulating layer provided above the substrate, and a display element including a first electrode provided above the insulating layer in the display area. The first electrode includes a transparent first conductive oxide layer and a transparent second conductive oxide layer covering the first conductive oxide layer. Further, a transmittance of the second conductive oxide layer is lower than that of the first conductive oxide layer.

Furthermore, in general, according to one embodiment, a manufacturing method of a display device includes forming an insulating layer above a substrate and forming a first electrode of a display element above the insulating layer. The first electrode includes a transparent first conductive oxide layer and a transparent second conductive oxide layer covering the first conductive oxide layer. Furthermore, formation of the first electrode includes forming the first conductive oxide layer by performing a first sputtering in an atmosphere containing no water vapor and forming the second conductive oxide layer by performing a second sputtering in an atmosphere containing water vapor.

These configuration of the display device and manufacturing method of the same can improve the yield of the display device.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

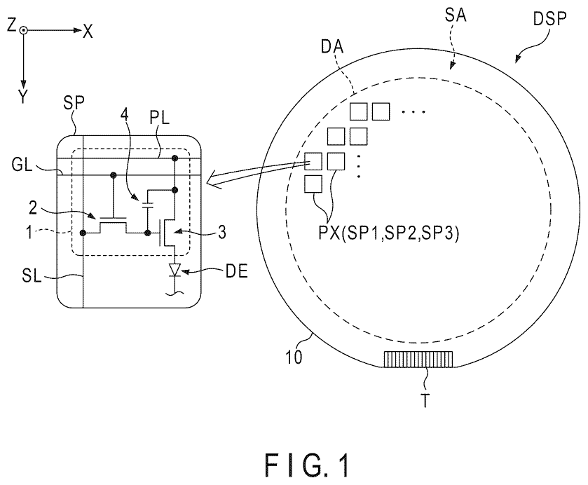

FIG. 1 is a view showing a configuration example of a display device DSP of the first embodiment. The display device DSP comprises an insulating substrate 10. The substrate 10 has a display area DA for displaying an image and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP that display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL supplying the pixel circuit 1 of each subpixel SP with scanning signals, a plurality of signal lines SL supplying the pixel circuit 1 of each subpixel SP with video signals, and a plurality of power lines PL. In the example of FIG. 1, the scanning lines GL and the power lines PL extend in the X-direction, and the signal lines SL extend in the Y-direction.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of the source electrode and the drain electrode is connected to the power line PL and the capacitor 4. The other is connected to a display element DE.

The configuration of the pixel circuit 1 is not limited to the example of the figure. For example, the pixel circuit 1 may comprise more thin-film transistors and capacitors.

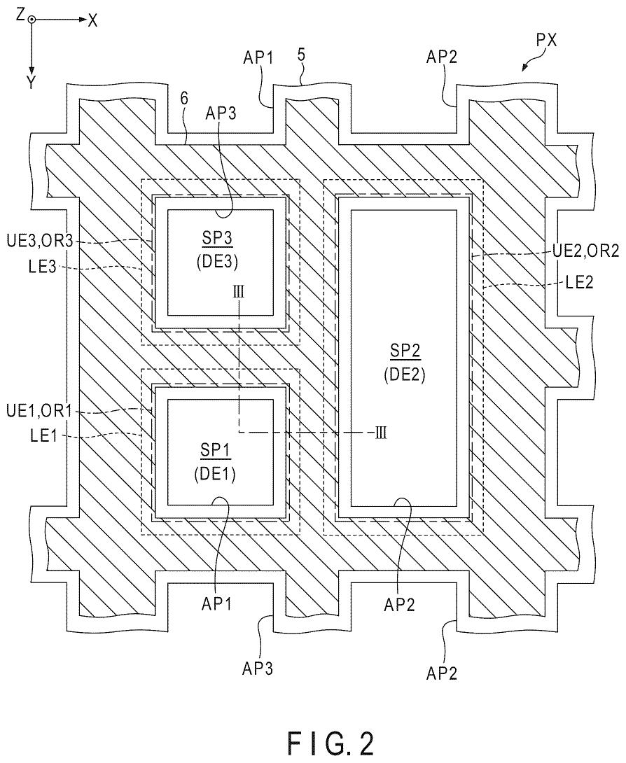

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel apertures AP1 and AP3 are rectangles having the same planar size. In contrast, the pixel aperture AP2 is a rectangle that is elongated in the Y-direction more than the pixel apertures AP1 and AP3 are. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

In the present embodiment, the lower electrodes LE1, LE2, and LE3 are examples of the first electrode. The upper electrodes UE1, UE2, and UE3 are examples of the second electrode.

Portions that overlap the pixel aperture AP1 of the lower electrode LE1, the upper electrode UE1, and the organic layer OR1 constitute a display element DE1 of the subpixel SP1. Portions that overlap the pixel aperture AP2 of the lower electrode LE2, the upper electrode UE2, and the organic layer OR2 constitute a display element DE2 of the subpixel SP2. Portions that overlap the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided above the rib layer 5. The partition 6 functions as lines which apply common voltage to the upper electrodes UE1, UE2, and UE3. The partition 6 entirely overlaps the rib layer 5 and has the same planar shape as that of the rib layer 5. The partition 6 surrounds each of the pixel apertures AP1, AP2, and AP3.

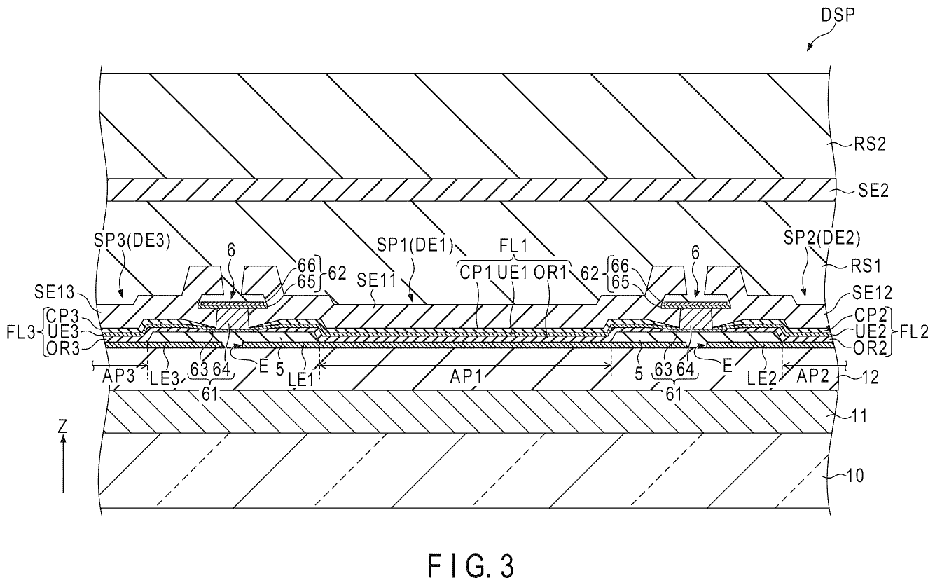

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. That is, the partition 6 has an overhang shape in which both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, both end portions of the bottom layer 63 protrude relative to the side surfaces of the stem layer 64.

In the example of FIG. 3, the upper portion 62 comprises a first top layer 65 and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13 are provided in the respective subpixels SP1, SP2 and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. Any two of the sealing layers SE11, SE12, and SE13 may contact each other above the partition 6.

For example, a gap is formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA).

The electrodes that constitute the touch panel may be provided on the sealing layer SE2. Further, color filters respectively corresponding to the colors of the subpixels SP1, SP2, and SP3 may be respectively provided above the display elements DE1, DE2, and DE3.

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). For example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (an organic insulating material) such as an epoxy resin or an acrylic resin.

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including light emitting layers. In one example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may have other structures such as a tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6 is composed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be composed of an insulating material.

The first top layer 65 of the partition 6 is formed of, for example, a metal material. The second top layer 66 of the partition 6 is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, an ITO (Indium Tin Oxide), an IZO (Indium Zinc Oxide), or an IGZO (Indium Gallium Zinc Oxide) may be used. The upper portion 62 may comprise three or more layers or may consist of a single layer. The upper portion 62 may further include a layer formed of an insulating material.

Common voltage is applied to the partition 6. This common voltage is applied to each of the upper electrodes UE1, UE2, and UE3 that contact the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light in the same color (for example, white). In this case, the display device DSP may comprise a color filter that converts the light emitted from the light emitting layers into light of colors corresponding to those of the subpixels SP1, SP2, and SP3. In addition, the display device DSP may comprise a layer including quantum dots that are excited by the light emitted from the light emitting layers to generate the light of colors corresponding to those of the subpixels SP1, SP2, and SP3.

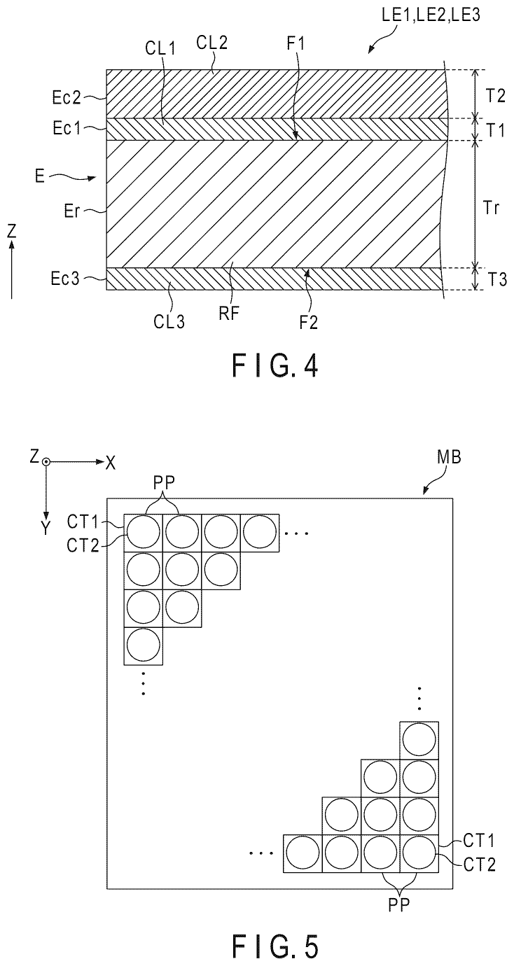

FIG. 4 is a schematic cross-sectional view showing an example of a configuration applicable to the lower electrodes LE1, LE2, and LE3. This figure shows the vicinity of end portions E of the lower electrodes LE1, LE2, and LE3. The end portions E are covered with the rib layer 5 (refer to FIG. 3).

In the present embodiment, the lower electrodes LE1, LE2, and LE3 comprise a reflective layer RF, a conductive oxide layer CL1 (the first conductive oxide layer), a conductive oxide layer CL2 (the second conductive oxide layer), and a conductive oxide layer CL3 (the third conductive oxide layer).

The conductive oxide layer CL1 covers an upper surface F1 of the reflective layer RF. The conductive oxide layer CL2 covers the conductive oxide layer CL1. The conductive oxide layer CL3 covers a lower surface F2 of the reflective layer RF.

The present embodiment assumes cases where the reflective layer RF is formed by silver (Ag) and the conductive oxide layers CL1, CL2, and CL3 are formed by an ITO. As other examples, the reflective layer RF may be formed by a metal material that differs from silver and has excellent reflectivity, or may have a multi-layer structure of metal materials. Further, the conductive oxide layers CL1, CL2, and CL3 may be formed by transparent conductive oxides other than an ITO, such as an IZO and an IGZO.

The reflective layer RF reflects the light emitted from the organic layers OR1, OR2, and OR3 upward. The conductive oxide layers CL1 and CL2 suppress oxidation of the reflective layer RF and improve the work function of the lower electrodes LE1, LE2, and LE3. Further, the conductive oxide layers CL1 and CL2 protect the reflective layer RF from etching performed after the formation of the lower electrodes LE1, LE2, and LE3 in the manufacturing of the display device DSP. The conductive oxide layer CL3 improves the adhesion between the lower electrodes LE1, LE2, and LE3 and the organic insulating layer 12.

The end portions E include an end portion Er of the reflective layer RF, an end portion Ec1 of the conductive oxide layer CL1, an end portion Ec2 of the conductive oxide layer CL2, and an end portion Ec3 of the conductive oxide layer CL3. In the example shown in FIG. 4, the end portions Er, Ec1, Ec2, and Ec3 align. That the end portions Er, Ec1, Ec2, and Ec3 align includes not only cases where these end portions align to the extent that they form a single plane but also cases where they are slightly offset but align compared to the overall size of the lower electrodes LE1, LE2, and LE3.

The reflective layer RF, the conductive oxide layer CL1, the conductive oxide layer CL2, and the conductive oxide layer CL3 have respective thicknesses Tr, T1, T2, and T3. In the example shown in FIG. 4, the thickness Tr is greater than each of the thicknesses T1, T2, and T3 (Tr>T1, T2, and T3). Further, the thickness T2 is greater than the thickness T1 (T1<T2). The thickness T3 is, for example, equivalent to the thickness T1 (T3=T1). In this case, the thickness T3 is smaller than the thickness T2 (T2>T3). The thicknesses T1 and T3 may differ from each other.

For example, the thickness T1 is 7 nm or more and 13 nm or less, and the thickness T2 is 15 nm or more and 20 nm or less. More specifically, for example, the thickness Tr is 100 nm, the thicknesses T1 and T3 are 7 nm, and the thickness T2 is 18 nm. However, the values of the thickness Tr, T1, T2, and T3 are not limited to these examples.

The following describes an example of the manufacturing method of the display device DSP.

In the manufacturing of the display device DSP, a large mother substrate is fabricated. The mother substrate comprises a plurality of areas (panel portions) each corresponding to the display device DSP. The following describes a configuration applicable to this mother substrate.

FIG. 5 is a schematic plan view of a mother substrate MB (a mother substrate for a display device) according to the present embodiment. The mother substrate MB comprises a plurality of panel portions PP provided in a matrix.

The outer shape of the panel portion PP corresponds to a cut line CT1 for cutting out each panel portion PP from the mother substrate MB. In the panel portion PP, a cut line CT2 corresponding to the outer shape of the display device DSP shown in FIG. 1 is provided.

In the manufacturing of the display device DSP, the mother substrate MB is cut along the cut line CT1, and each of the panel portions PP is cut out. Furthermore, the panel portions PP are cut along the cut line CT2, and the portions corresponding to the display device DSP are cut out.

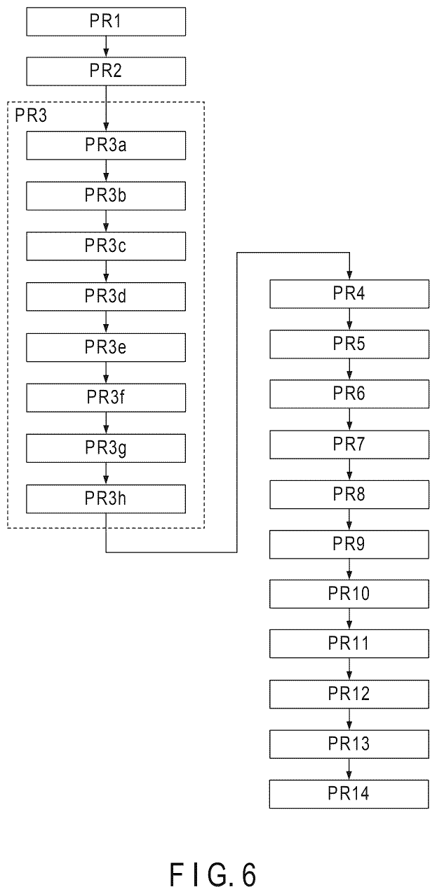

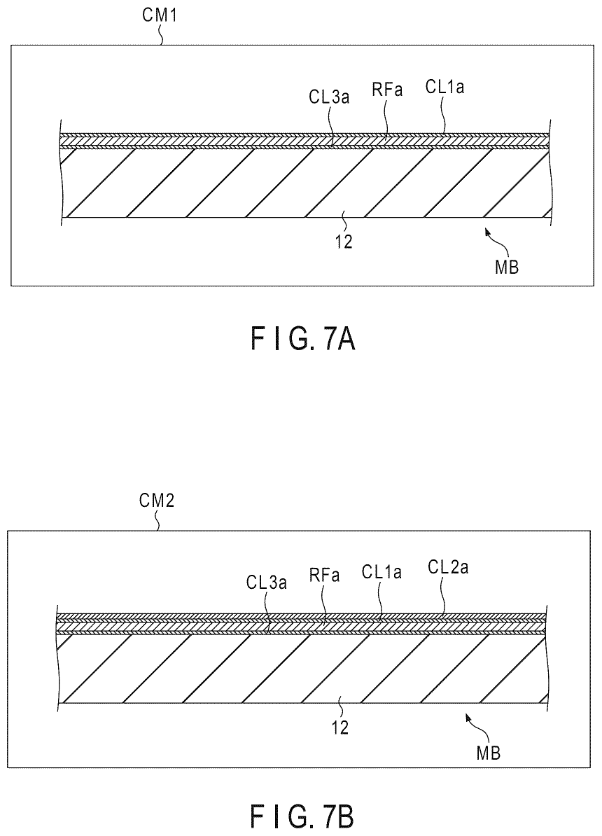

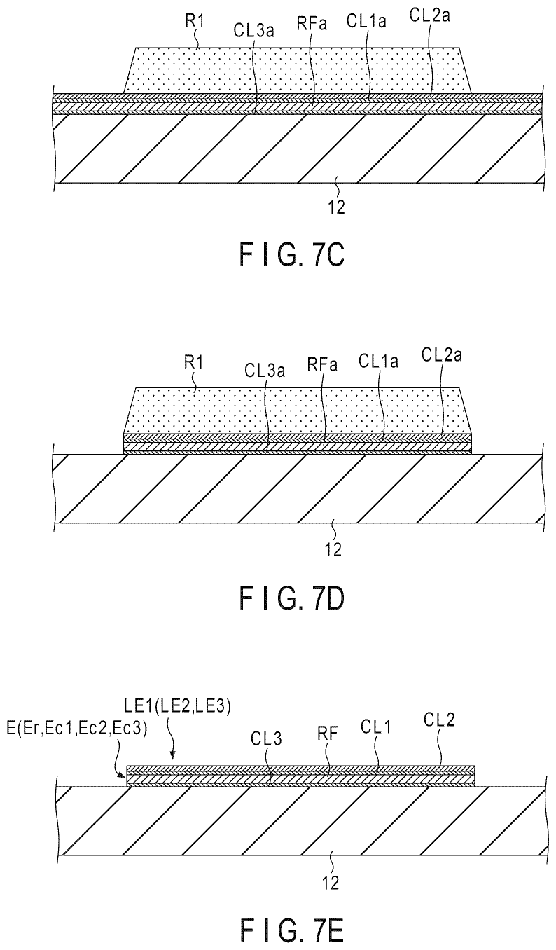

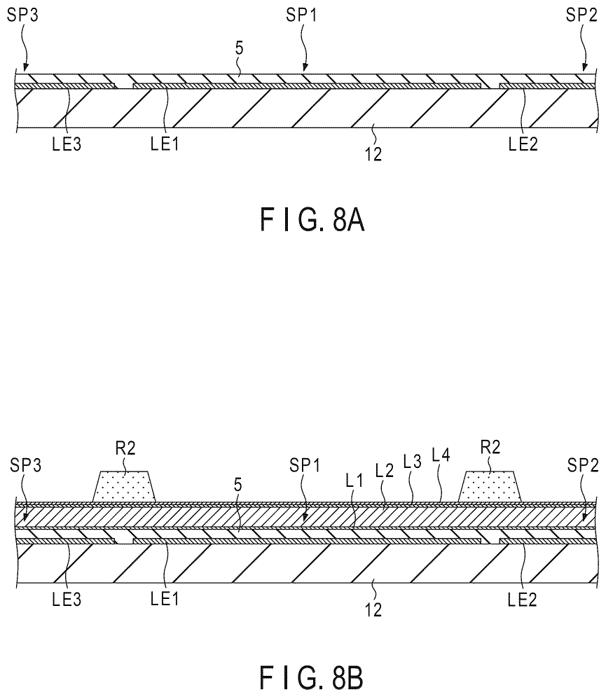

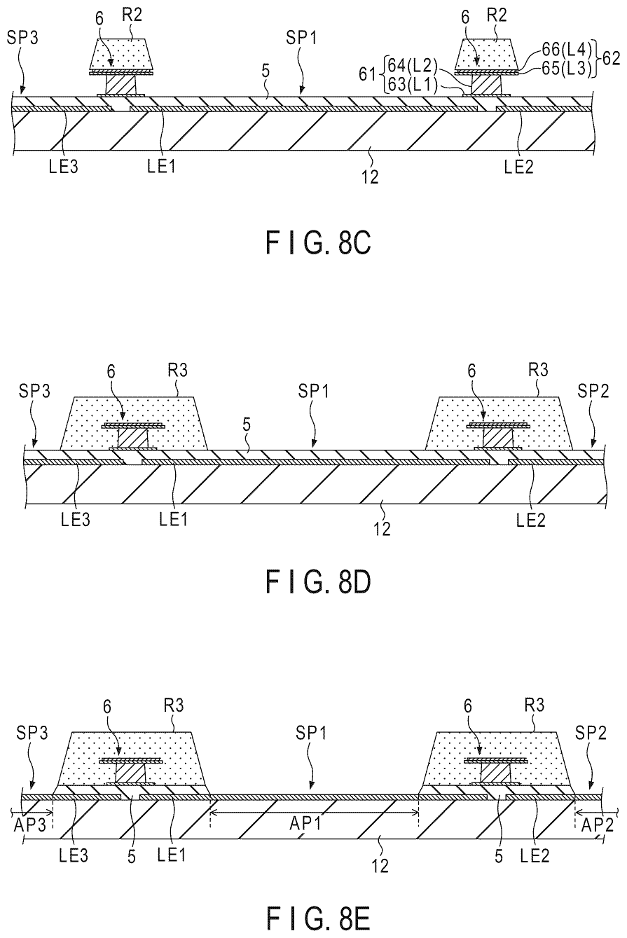

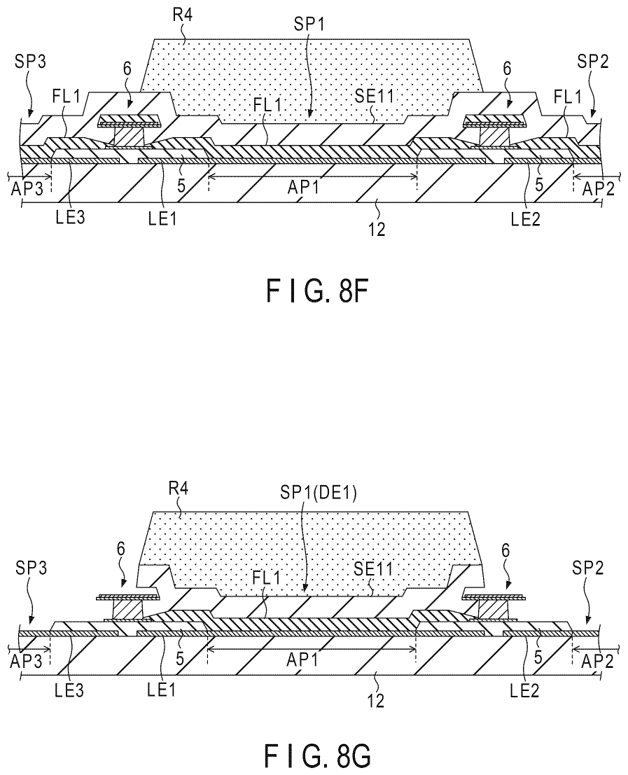

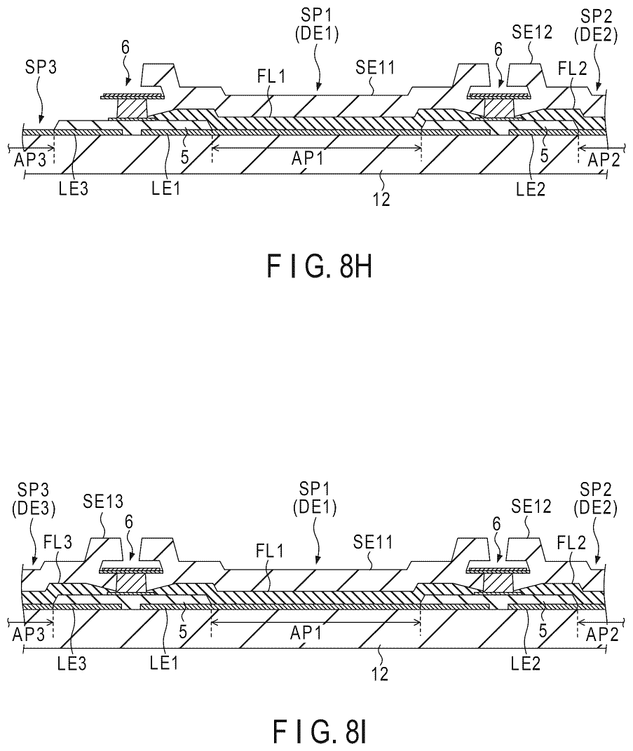

FIG. 6 is a flowchart showing an example of the manufacturing method of the display device DSP. FIG. 7A to FIG. 7E and FIG. 8A to FIG. 8I are schematic cross-sectional views showing the manufacturing process of the display device DSP. FIG. 7A to FIG. 7E and FIG. 8A to FIG. 8I mainly focus on the display area DA and omit the components below the organic insulating layer 12.

In the formation of the panel portions PP, first, the circuit layer 11 is formed above the substrate 10 of the mother substrate MB (the process PR1 in FIG. 6). Further, the organic insulating layer 12 covering the circuit layer 11 is formed (the process PR2 in FIG. 6). After the process PR2, a process for forming the lower electrodes LE1, LE2, and LE3 are performed (the process PR3 in FIG. 6).

In the process PR3, a conductive oxide layer CL3a to be processed into the conductive oxide layer CL3 is formed on the organic insulating layer 12 (the process PR3a in FIG. 6), a reflective layer RFa to be processed into the reflective layer RF is formed on the conductive oxide layer CL3a (the process PR3b in FIG. 6), a conductive oxide layer CL1a to be processed into the conductive oxide layer CL1 is formed on the reflective layer RFa (the process PR3c in FIG. 6) as shown in FIG. 7A. In the present embodiment, the conductive oxide layer CL3a and the conductive oxide layer CL1a each are formed of an ITO, and the reflective layer RFa is formed of silver.

For example, the conductive oxide layer CL3a, the reflective layer RFa, and the conductive oxide layer CL1a can be formed by sputtering in the same chamber CM1. In this case, the sputtering targets for the conductive oxide layer CL3a and the conductive oxide layer CL1a, which are ITO, may be the same. As another example, the conductive oxide layer CL3a, the reflective layer RFa, and the conductive oxide layer CL1a may be formed by sputtering in separate chambers.

After the formation of the conductive oxide layer CL3a, the reflective layer RFa, and the conductive oxide layer CL1a, a conductive oxide layer CL2a to be processed into the conductive oxide layer CL2 is formed on the conductive oxide layer CL1a by sputtering as shown in FIG. 7B (the process PR3d in FIG. 6). In the present embodiment, the conductive oxide layer CL2a is formed of an ITO. For example, the sputtering for forming the conductive oxide layer CL2a may be performed in a chamber CM2, which is different from the chamber CM1.

During the sputtering for forming the conductive oxide layer CL3a, the reflective layer RFa, the conductive oxide layer CL1a, and the conductive oxide layer CL2a, the inside of each of the chambers CM1 and CM2 is filled with an inert gas, such as argon (Ar) gas. However, water vapor (H₂O) is introduced into the chamber CM2. On the other hand, water vapor is not introduced into the chamber CM1.

In this way, although the conductive oxide layers CL1a and CL2a are both formed by an ITO, the sputtering for forming the conductive oxide layer CL1a (the first sputtering) is performed in an atmosphere that does not contain water vapor, and the sputtering for forming the conductive oxide layer CL2a (the second sputtering) is performed in an atmosphere that contains water vapor.

The above describes the example where the sputtering for forming the conductive oxide layers CL1a and CL2a is performed in separate chambers. As another example, these sputtering steps may be performed in the same chamber.

After the process PR3d, a planar resist R1 corresponding to lower electrodes LE1, LE2, and LE3 is provided on the conductive oxide layer CL2a as shown in FIG. 7C (the process PR3e in FIG. 6). Furthermore, etching using the resist R1 as a mask is performed (the process PR3f in FIG. 6). This removes the portions exposed from the resist R1 of the conductive oxide layers CL1a, CL2a, and CL3a and the reflective layer RFa as shown in FIG. 7D. For example, the etching is wet etching.

After the process PR3f, the resist R1 is removed (stripped) (the process PR3g in FIG. 6). Further, the conductive oxide layers CL1a, CL2a, and CL3a formed of an ITO are calcined (the process PR3h in FIG. 6).

These steps provide the lower electrodes LE1, LE2, and LE3 in which the conductive oxide layer CL3, the reflective layer RF, the conductive oxide layer CL1, and the conductive oxide layer CL2 are stacked in this order as shown in FIG. 7E.

In this example, the conductive oxide layers CL1a, CL2a, and CL3a and the reflective layer RFa are etched using the same resist R1 as a mask. Therefore, the end portions Er, Ec1, Ec2, and Ec3 of the reflective layer RF and the conductive oxide layers CL1, CL2, and CL3 align at the end portions of the lower electrodes LE1, LE2, and LE3.

The sputtering for forming the conductive oxide layer CL2a in the process PR3d is performed in an atmosphere containing water vapor. Thus, water is added to the conductive oxide layer CL2a. In this case, in the stage before calcining in the process PR3h, the crystallinity of the conductive oxide layer CL2a is lower than that of the conductive oxide layer CL1a formed in an atmosphere containing no water vapor. Thus, the etching rate of the conductive oxide layer CL2a in the etching in the process PR3f is greater than that of the conductive oxide layer CL1a in the etching. The crystallinity of each of the conductive oxide layers CL1a and CL2a is increased by the calcining in the process PR3h. Further, this calcining removes the water added to the conductive oxide layer CL2a.

After the formation of the lower electrodes LE1, LE2, and LE3, the rib layer 5 covering the lower electrodes LE1, LE2, and LE3 is formed on the entire mother substrate MB as shown in FIG. 8A (the process PR4 in FIG. 6). At this time, the pixel apertures AP1, AP2, and AP3 are not provided in the rib layer 5. The rib layer 5 may be formed by chemical vapor deposition (CVD).

After the formation of the rib layer 5, a process for forming the partition 6 is performed (the process PR5 in FIG. 6). In the process PR5, a first layer L1 to be processed into the bottom layer 63, a second layer L2 to be processed into the stem layer 64, a third layer L3 to be processed into the first top layer 65, and a fourth layer L4 to be processed into the second top layer 66 are subsequently formed on the entire mother substrate MB as shown in FIG. 8B. Further, a resist R2 is provided on the fourth layer L4. The resist R2 has been patterned into the shape of the partition 6. The first layer L1, the second layer L2, the third layer L3, and the fourth layer L4 are formed by, for example, sputtering.

Subsequently, the first layer L1, the second layer L2, the third layer L3, and the fourth layer L4 are patterned using the resist R2 as a mask. In one example, the first layer L1 is formed of a titanium nitride, the second layer L2 is formed of aluminum, the third layer L3 is formed of titanium, and the fourth layer L4 is formed of an ITO. In this case, the above patterning process may include wet etching for removing the portion exposed from the resist R2 of the fourth layer L4, dry etching for removing the portions exposed from the resist R2 of the first, second, and third layers L1, L2, and L3, and wet etching for reducing the width of the second layer L2.

The process PR5 completes the formation of the partition 6 in the display area DA as shown in FIG. 8C. After the formation of the partition 6, the resist R2 is removed (stripped).

Subsequently, a process for providing the pixel apertures AP1, AP2, and AP3 is performed (the process PR6 in FIG. 6). In this process PR6, a resist R3 covering the partition 6 is formed as shown in FIG. 8D. Further, dry etching for the rib layer 5 is performed using the resist R3 as a mask. This dry etching forms the pixel apertures AP1, AP2, and AP3 from which the respective lower electrodes LE1, LE2, and LE3 are exposed, in the rib layer 5 as shown in FIG. 8E. After the dry etching described above, the resist R3 is removed (stripped). The pixel apertures AP1, AP2, and AP3 may be formed prior to the formation of the partition 6.

After the process PR6, a process for forming the display element DE1 is performed (the process PR7 in FIG. 6). In the formation of the display element DE1, first, the stacked film FL1 and the sealing layer SE11 are formed on the entire mother substrate MB as shown in FIG. 8F.

As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD. The stacked film FL1 is divided into a plurality of portions by the partition 6 having an overhang shape. The sealing layer SE11 continuously covers these portions, into which the stacked film FL1 has been divided, and the partition 6.

Subsequently, the stacked film FL1 and the sealing layer SE11 are patterned. In this patterning, a resist R4 is provided on the sealing layer SE11 as shown in FIG. 8F. The resist R4 covers the subpixel SP1 and a portion of the partition 6 around the subpixel SP1.

Thereafter, the etching process using the resist R4 as a mask is performed. This process removes the portions exposed from the resist R4 of the stacked film FL1 and the sealing layer SE11 as shown in FIG. 8G. That is, the portions overlapping the lower electrode LE1 of the stacked film FL1 and the sealing layer SE11 remain, and the other portions are removed. This forms the display element DE1 in the subpixel SP1. This etching process may include wet etching and dry etching performed in order for the sealing layer SE11, the cap layer CP1, the upper electrode UE1, and the organic layer OR1. After these etching processes, the resist R4 is removed (stripped).

After the process PR7, a process for forming the display element DE2 is performed (the process PR8 in FIG. 6). The display element DE2 can be formed by the same procedure as that of the display element DE1. That is, in the formation of the display element DE2, the stacked film FL2 and the sealing layer SE12 are formed in the entire mother substrate MB. The stacked film FL2 includes the organic layer OR2 contacting the lower electrode LE2 through the pixel aperture AP2, the upper electrode UE2 covering the organic layer OR2, and the cap layer CP2 covering the upper electrode UE2 as shown in FIG. 3.

The organic layer OR2, the upper electrode UE2, and the cap layer CP2 may be formed by, for example, vapor deposition. The sealing layer SE12 may be formed by, for example, CVD. Patterning these stacked film FL2 and sealing layer SE2 forms the display element DE2 in the subpixel SP2 as shown in FIG. 8H.

After the process PR8, a process for forming the display element DE3 is performed (the process PR9 in FIG. 6). The display element DE3 can be formed by the same procedures as those of the display elements DE1 and DE2. Specifically, when the display element DE3 is formed, the stacked film FL3 and the sealing layer SE13 are formed in the entire mother substrate MB. The stacked film FL3 includes the organic layer OR3 contacting the lower electrode LE3 through the pixel aperture AP3, the upper electrode UE3 covering the organic layer OR3, and the cap layer CP3 covering the upper electrode UE3 as shown in FIG. 3.

The organic layer OR3, the upper electrode UE3, and the cap layer CP3 may be formed by, for example, vapor deposition. The sealing layer SE13 may be formed by, for example, CVD. Patterning these stacked film FL3 and sealing layer SE13 forms the display element DE3 in the subpixel SP3 as shown in FIG. 8I.

Here, the above description assumes that the display elements DE1, DE2, and DE3 are formed in this order. However, the display elements DE1, DE2, and DE3 may be formed in another order.

After the formation of the display elements DE1, DE2, and DE3, the resin layer RS1 is formed, for example, by the ink-jet method (the process PR10 in FIG. 6). After the process PR10, the sealing layer SE2 covering the resin layer RS1 is formed by, for example, CVD (the process PR11 in FIG. 6). Further, the resin layer RS2 covering the sealing layer SE2 is formed by, for example, the ink-jet method (the process PR12 in FIG. 6).

After the process PR11, the mother substrate MB is cut along the cut line CT1 (the process PR13 in FIG. 6). This cuts out each panel portion PP. Further, the panel portion PP is cut along the cut line CT2 (the process PR14 in FIG. 6). This completes the display device DSP. For example, laser cutting with infrared irradiation along the cut lines CT1 and CT2 may be adopted for cutting in the processes PR13 and PR14. The cutting in the processes PR13 and PR14 may be performed by other methods such as scribe cutting.

In the above present embodiment, the conductive oxide layers CL1 and CL2 are provided on the reflective layers RF on the lower electrodes LE1, LE2, and LE3. If a sole conductive oxide layer is formed instead of these conductive oxide layers CL1 and CL2, the following problems may arise.

That is, if the conductive oxide layer on the reflective layer RF has defects such as minute pinholes, the etching liquid may reach the reflective layer RF through the defects during various wet etching processes after the formation of the lower electrodes LE1, LE2, and LE3. This may result in loss of at least part of the reflective layer RF. In contrast, forming the conductive oxide layer on the reflective layer RF to be thicker can suppress the occurrence of defects such as pinholes. However, forming the conductive oxide layer on the reflective layer RF to be thicker requires longer time for sputtering. Thus, heat generated in the sputtering easily accumulates in the conductive oxide layer. If crystallization of the conductive oxide layer proceeds due to this heat, the complete removal of the crystallized conductive oxide layer may fail during the etching in the process PR3f. This may result in the conductive oxide layer remaining in unintended positions.

In contrast, in the present embodiment, the conductive oxide layer on the reflective layer RF is divided into the conductive oxide layer CL1 and the conductive oxide layer CL2. Further, as described above, the crystallinity of the conductive oxide layer CL2a, which serves as the base of the conductive oxide layer CL2, which is its upper layer, is low due to addition of water. The crystallization start temperature of the conductive oxide layer CL2a is higher than that in cases not involving water addition. Thus, even when the conductive oxide layer CL2a is formed to be thick, the conductive oxide layer CL2a is not easily crystallized by the heat generated in the sputtering. Further, the heat does not easily affect the conductive oxide layer CL1a covered with the conductive oxide layer CL2a. Thus, crystallization of the conductive oxide layer CL1a is suppressed as well. Thus, the conductive oxide layers CL1a and CL2a can be sufficiently removed by etching in the process PR3f. This improves the yield of the display device DSP.

Even if the conductive oxide layer CL2a is formed directly on the reflective layer RFa, the reflective layer RFa may oxidize due to water vapor during the formation of the conductive oxide layer CL2a or moisture contained in the conductive oxide layer CL2a. On the other hand, when the conductive oxide layer CL1a to which water is not added is provided between the reflective layer RFa and the conductive oxide layer CL2a as in the present embodiment, oxidation of the reflective layer RFa can be suppressed.

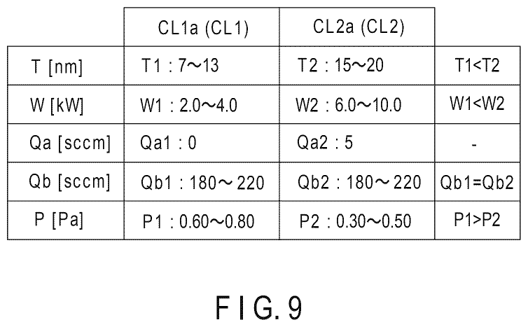

Here, the following describes film formation conditions to be applied to the conductive oxide layers CL1a and CL2a to achieve the above effects. FIG. 9 is a table showing an example of the film formation conditions. Here, for each of the conductive oxide layers CL1a and CL2a, the preferred ranges of thicknesses T [nm], film formation power W [KW] applied to the target during sputtering, water vapor flow rate Qi [sccm] to the atmosphere during sputtering, argon flow rate Qb [sccm] to the atmosphere during sputtering, and pressure P [Pa] of the atmosphere during sputtering are shown.

The relationship between the thickness T1 of the conductive oxide layer CL1a and the thickness T2 of the conductive oxide layer CL2a is the same as the one described above for the conductive oxide layers CL1 and CL2 in the explanation on FIG. 4. That is, the thickness T1 is 7 nm or more and 13 nm or less, and the thickness T2 is 15 nm or more and 20 nm or less. Further, the relationship T1<T2 is satisfied. In this manner, decreasing the thickness T1 can suppress excessive heat accumulation and crystallization of the conductive oxide layer CL1a due to that heat in the formation of the conductive oxide layer CL1a. Even if the conductive oxide layer CL2a formed under water-added conditions is formed to be thicker, this conductive oxide layer CL2a is difficult to crystallize as described above.

The film formation power W1 during the sputtering of the conductive oxide layer CL1a is 2.0 KW or more and 4.0 kW or less. In contrast, the film formation power W2 during the sputtering of the conductive oxide layer CL2a is 6.0 kW or more and 10.0 kW or less. That is, the relationship W1<W2 is satisfied.

The water vapor flow rate Qa during the sputtering of the conductive oxide layer CL1a is 0 sccm. In contrast, for example, the water vapor flow rate Qa during the sputtering of the conductive oxide layer CL2a is 5 sccm.

The argon flow rate Qb1 during the sputtering of the conductive oxide layer CL1a is 180 sccm or more and 220 sccm or less. Further, the argon flow rate Qb2 during the sputtering of the conductive oxide layer CL2a is 180 sccm or more and 220 sccm or less. That is, Qb1 and Qb2 are equivalent to each other.

The pressure P1 during the sputtering of the conductive oxide layer CL1a is 0.60 Pa or more and 0.80 Pa or less. In contrast, the pressure P2 during the sputtering of the conductive oxide layer CL2a is 0.30 Pa or more and 0.50 Pa or less. That is, the relationship P1>P2 is satisfied.

The conductive oxide layers CL1 and CL2 have these different film formation conditions. This results in differences in the transmittances. Specifically, the transmittance of the conductive oxide layer CL2 is lower than that of the conductive oxide layer CL1. The following describes this point in detail.

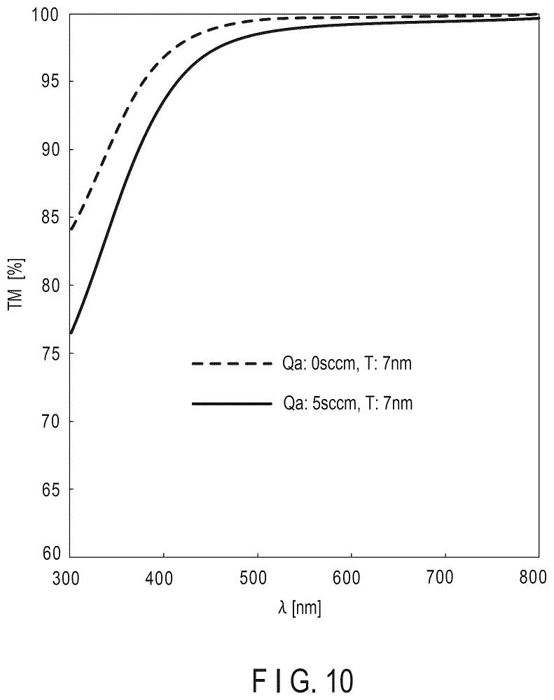

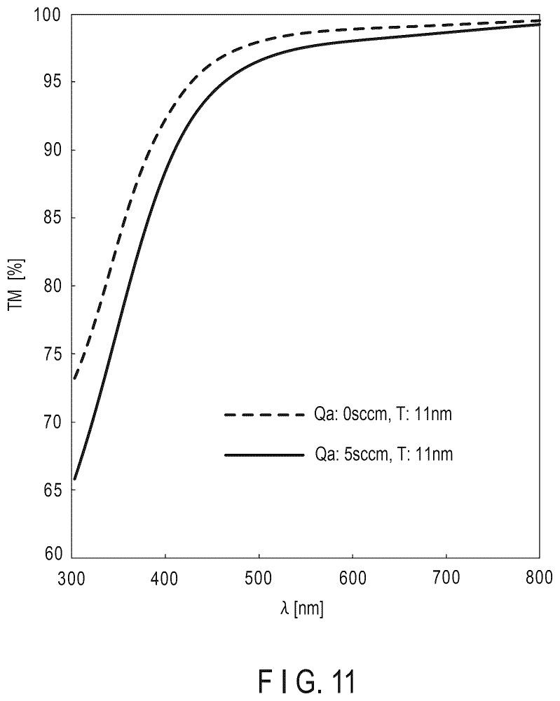

FIG. 10 to FIG. 12 are graphs showing the transmittances of these conductive oxide layers formed of an ITO of 7 nm, 11 nm, and 25 nm, respectively. In all graphs, the horizontal axis represents the wavelength λ of light [nm], and the vertical axis represents the transmittance TM [%]. The conductive oxide layers under measurement are formed by sputtering and then calcined to be crystallized.

In FIG. 10 to FIG. 12, the broken curved lines indicate the transmittance distribution of conductive oxide layers formed without water addition (Qa=0 sccm). The solid curved lines indicate the transmittance distribution of the conductive oxide layer formed with water addition (Qa=5 sccm). In all of FIG. 10 to FIG. 12, the transmittance decreases in most wavelength ranges in cases involving water addition. In particular, the decrease tends to be greater in the short-wavelength range (for example, the blue wavelength range). Further, the transmittance decreases as the thickness of the conductive oxide layer increases.

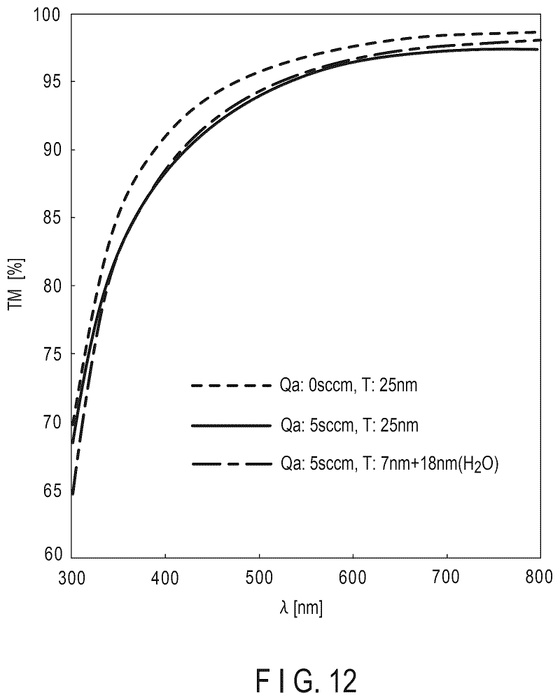

FIG. 12 also shows by dashed lines the transmittance distribution of a stacked layer body composed of an ITO layer formed at a thickness of 7 nm without water addition (Qa=0 sccm) and an ITO layer formed at a thickness of 18 nm with water addition (Qa=5 sccm). The transmittance distribution of this stacked layer body is generally equivalent to that of the conductive oxide layer formed at 25 nm with water addition (shown by solid lines), but shows a slight improvement in the transmittance in the wavelength range at 400 nm or more.

As the graphs in FIG. 10 to FIG. 12 show, the transmittance of the conductive oxide layer CL2 formed with water addition is lower than that of the conductive oxide layer CL1 formed without water addition. Further, as the conductive oxide layer CL2 is formed to be thinner, the transmittance of the conductive oxide layer CL2 increases. In light of these points and also in terms of sufficiently transmitting light reflected by the reflective layer RF, the thickness T2 of the conductive oxide layer CL2 is desirably maintain within the range shown in the table in FIG. 9.

### Second Embodiment

Next, the following describes the second embodiment. The present embodiment discloses other configurations applicable to the lower electrodes LE1, LE2, and LE3.

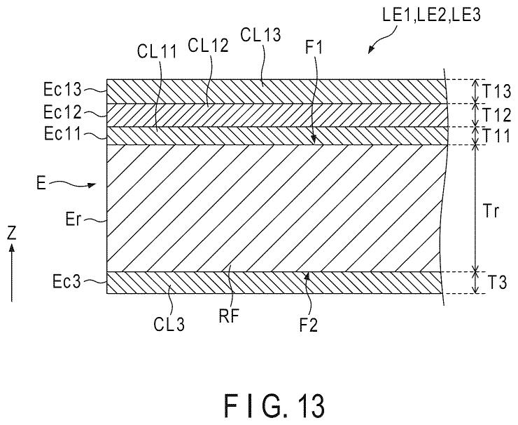

FIG. 13 is a schematic cross-sectional view showing a configuration example of the lower electrodes LE1, LE2, and LE3 of the second embodiment. In the present embodiment, conductive oxide layers CL11, CL12, and CL13 are provided in order on the reflective layer RF. Each of these conductive oxide layers CL11, CL12, and CL13 is formed of an ITO. Further, the conductive oxide layers CL11, CL12, and CL13 may be formed by transparent conductive oxides other than an ITO, such as an IZO and an IGZO.

The conductive oxide layers CL11, CL12, and CL13 are formed by sputtering under film formation conditions without water addition as in the conductive oxide layer CL1 (the conductive oxide layer CL1a) in the first embodiment. For example, the conductive oxide layers CL11, CL12, and CL13 are formed by sputtering in the same chamber. However, after the formation of the conductive oxide layer CL11, the mother substrate MB is once removed from the chamber and cooled before the formation of the conductive oxide layer CL12. Similarly, after the formation of the conductive oxide layer CL12, the mother substrate MB is once removed from the chamber and cooled before the formation of the conductive oxide layer CL13.

Forming the conductive oxide layers CL11, CL12, and CL13 in this manner can suppress the temperature rise due to heat accumulation during sputtering than forming thick conductive oxide layers continuously on the reflective layer RF. As a result, this configuration can suppress the crystallization of the conductive oxide layers CL11, CL12, and CL13 due to the heat generated in the sputtering such as that described above in the first embodiment.

The conductive oxide layers CL11, CL12, and CL13 have respective thicknesses T11, T12, and T13. In one example, the thicknesses T11, T12, and T13 are 7 nm or more and 13 nm or less. More specifically, the thickness T11 is 7 nm, and each of the thicknesses T12 and T13 is 9 nm. However, the values of the thickness T11, T12, and T13 are not limited to these examples.

The present embodiment discloses the example where the conductive oxide layer on the reflective layer RF is divided into three layers, but the conductive oxide layer may be divided into four or more layers.

The configurations in the first and second embodiments may be combined as appropriate. For example, when the conductive oxide layer on the reflective layer RF is divided into three layers or four layers or more as in the second embodiment, the uppermost layer may be formed under film formation conditions with water addition as in the conductive oxide layer CL2 (the conductive oxide layer CL2a) in the first embodiment.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a substrate having a display area for displaying images;
an insulating layer provided above the substrate; and
a display element including a first electrode provided above the insulating layer in the display area, wherein
the first electrode includes:
a transparent first conductive oxide layer; and
a transparent second conductive oxide layer covering the first conductive oxide layer, and
a transmittance of the second conductive oxide layer is lower than that of the first conductive oxide layer.

2. The display device of claim 1, wherein
an end portion of the first conductive oxide layer and an end portion of the second conductive oxide layer align.

3. The display device of claim 1, wherein
the second conductive oxide layer is thicker than the first conductive oxide layer.

4. The display device of claim 1, wherein
the first electrode further includes:
a reflective layer covered with the first conductive oxide layer; and
a transparent third conductive oxide layer covered with the reflective layer.

5. The display device of claim 4, wherein
the third conductive oxide layer is thinner than the second conductive oxide layer.

6. The display device of claim 1, wherein
each of the first conductive oxide layer and the second conductive oxide layer is formed of an ITO.

7. The display device of claim 1, further comprising:
a rib layer covering an end portion of the first electrode and having a pixel aperture overlapping the first electrode, wherein
the display element further includes:
an organic layer contacting the first electrode through the pixel aperture and emitting light in response to application of a voltage; and
a second electrode covering the organic layer.

8. The display device of claim 7, further comprising:
a partition covering the pixel aperture, wherein
the partition includes:
a lower portion provided above the rib layer and having conductivity; and
an upper portion having an end portion protruding relative to a side surface of the lower portion, and
the second electrode contacts the lower portion.

9. A manufacturing method of a display device, the method comprising:
forming an insulating layer above a substrate; and
forming a first electrode of a display element above the insulating layer, wherein
the first electrode includes:
a transparent first conductive oxide layer; and
a transparent second conductive oxide layer covering the first conductive oxide layer, and
the forming of the first electrode includes:
forming the first conductive oxide layer by performing a first sputtering in an atmosphere containing no water vapor; and
forming the second conductive oxide layer by performing a second sputtering in an atmosphere containing water vapor.

10. The manufacturing method of claim 9, wherein
the forming of the first electrode includes:
providing a resist having a shape of the first electrode on the second conductive oxide layer; and
removing portions of the first conductive oxide layer and the second conductive oxide layer exposed from the resist by an etching.

11. The manufacturing method of claim 10, wherein
an etching rate of the second conductive oxide layer in the etching is greater that of the first conductive oxide layer in the etching.

12. The manufacturing method of claim 9, wherein
power applied to a target in the second sputtering is greater than power applied to a target in the first sputtering.

13. The manufacturing method of claim 9, wherein
pressure of the atmosphere in the second sputtering is lower than that of the atmosphere in the first sputtering.

14. The manufacturing method of claim 13, wherein
the pressure of the atmosphere in the first sputtering is 0.6 Pa or more and 0.8 Pa or less, and
the pressure of the atmosphere in the second sputtering is 0.3 Pa or more and 0.5 Pa or less.

15. The manufacturing method of claim 9, wherein
the first conductive oxide layer is formed to be thinner than the second conductive oxide layer.

16. The manufacturing method of claim 15, wherein
a thickness of the first conductive oxide layer is 7 nm or more and 13 nm or less, and
a thickness of the second conductive oxide layer is 15 nm or more and 20 nm or less.

17. The manufacturing method of claim 9, wherein
the forming of the first electrode further includes:
forming a transparent third conductive oxide layer before the forming of the first conductive oxide layer; and
forming a reflective layer covering the third conductive oxide layer, wherein
the first conductive oxide layer is formed to cover the reflective layer.

18. The manufacturing method of claim 9, wherein
each of the first conductive oxide layer and the second conductive oxide layer is formed of an ITO.

19. The manufacturing method of claim 9, further comprising:
forming a rib layer covering an end portion of the first electrode and having a pixel aperture overlapping the first electrode;
forming an organic layer contacting the first electrode through the pixel aperture and emitting light in response to application of a voltage; and
forming a second electrode covering the organic layer.

20. The manufacturing method of claim 19, further comprising:
forming a partition surrounding the pixel aperture after the forming of the rib layer and before the forming of the organic layer and the second electrode, wherein
the partition comprises:
a lower portion provided above the rib layer and having conductivity; and
an upper portion having an end portion protruding relative to a side surface of the lower portion, wherein
the second electrode is formed to contact the lower portion.
